(19) United States
(12) Patent Application Publication
(10) Pub. No.: US 2005/0145963 A1
(43) Pub. Date: Jul. 7, 2005

(54) Manufacturing method of solid-state image pickup device, and solid-state image pickup device

(75) Inventor: Satoshi Saitoh, Fukuyama-shi (JP)

Correspondence Address: EDWARDS & ANGELL, LLP, P.O. BOX 55874, BOSTON, MA, 02205, US

(73) Assignee: Sharp Kabushiki Kaisha

(21) Appl. No.: 11/021,846

(22) Filed: Dec. 23, 2004

(30) Foreign Application Priority Data
Dec. 25, 2003 (JP) 2003-431563

(51) Int. Cl. H01L 21/00; H01L 27/14; H01L 31/00

(52) U.S. Cl. 257/428; 438/57; 438/514

(57) ABSTRACT

A p-type region of a light receiving section is formed by implanting boron ions from the direction normal to a semiconductor substrate. The ion implantation conditions of boron are a few hundred to 4 MeV for the ion implantation energy, 1×10¹⁰ to 1×10¹² ions/cm² for the implanted dose, and 0 degree±0.2 degrees for an ion implantation angle (θ) with respect to the direction normal to the surface of the semiconductor substrate.

### CROSS-REFERENCE TO RELATED APPLICATION

This non-provisional application claims priority under 35 U.S.C. §119(a) on Patent Application No. 2003-431563 filed in Japan on Dec. 25. 2003, the entire contents of which are hereby incorporated by reference.

### BACKGROUND OF THE INVENTION

The present invention relates to a method of manufacturing a solid-state image pickup device comprising a light receiving section formed by ion implantation, and also relates to a solid-state image pickup device.

In a conventional manufacturing method of a solid-state image pickup device, after a transfer section and a light receiving section having a p-n junction (photoelectric conversion region) are formed by implanting ions into a semiconductor substrate, such as silicon, and a gate oxide film is formed, a gate electrode is formed by a polycrystalline material obtained by CVD (chemical vapor deposition). The light receiving section comprises a p-well formed by implanting boron ions as a p-type impurity deep at a high energy into an n-type substrate, a p-n junction formed by implanting phosphorus ions as an n-type impurity more shallowly than the p-well only into a pixel section, and a p⁺ region formed by boron ions implanted shallowly in the surface of the semiconductor substrate so as to prevent a leakage current at the Si—SiO₂ interface of the semiconductor substrate surface. As the ion implantation conditions at this time, in general, an ion implantation angle is selected to avoid channeling, and ions are implanted.

FIG. 1 is a cross sectional view for explaining a state during a conventional process of manufacturing a solid-state image pickup device. Note that oblique lines representing a cross section are all omitted to allow the drawing to be easily seen. After forming an epitaxial layer 22 on a semiconductor substrate 21, a resist film 23 is coated to form a light receiving section, and then an aperture section 23h corresponding to a pattern of the light receiving section is formed. Next, in order to form a p-type region 25 of the light receiving section, boron ions are implanted into the semiconductor substrate 21 by ion implantation 24. An ion implantation angle θ at this time is usually set at 7 degrees with respect to a normal 21 v to the semiconductor substrate 21.

In a known example of manufacturing method of a solid-state image pickup device, the angle of ion implantation performed in the ion implantation process for forming a sensor section (light receiving section) is tilted within a range of 7 degrees to 45 degrees from the wafer normal, and this ion implantation process is carried out by two or more ion implantation steps with ion implantation angles tilted in mutually different directions from the wafer normal (see, for example, Japanese Patent Application Laid Open No. 10-209423 (1998)). According to this method, by performing the ion implantation process for forming the sensor section by tilting the ion implantation direction within a range of 7 degrees to 45 degrees from the wafer normal and performing ion implantation two or more times by varying the ion implantation direction, an impurity diffusion region of the sensor section can be expanded laterally in the tilted direction. Such a method is employed because so-called channeling occurs at angles of not greater 7 degrees and angles of not smaller than 45 degrees with respect to the silicon (100) crystal (the surface of the semiconductor substrate is the (100) crystal face).

Channeling is a phenomenon where ions reach a region deep inside the crystal without scattering when implanting ions into the crystal lattice from a specific direction (see, for example, Japanese Patent Application Laid Open No. 5-160382 (1993)). Therefore, the ion implantation angle θ is usually set at 7 degrees to prevent axial channeling, and a rotation angle Φ is set by avoiding 45 degrees, 135 degrees, 225 degrees and 315 degrees (hereinafter represented by 45 degrees) to prevent planar channeling for a wafer with an orientation flat in the <110> direction.

As other conventional manufacturing method of a solid-state image pickup device, there is a known method that prevents planar channeling by almost aligning the direction of an edge on the photodiode (light receiving section) side of the transfer gate (portion corresponding to the gage electrode between the charge transfer section and the light receiving section) with the <100> direction within a deviation of ±15 degrees and implanting ions parallel to the edge direction (see, for example, Japanese Patent Application Laid Open No. 5-160382 (1993)). Accordingly, the photodiodes arranged in a staggered manner with respect to transfer gates formed on the same wafer can have uniform potential compared to the conventional example, and it is possible to prevent reading errors due to an energy barrier and improve the yield. In other words, in order to stabilize the characteristics of the solid-state pickup device, it is necessary to implant ions under ion implantation conditions that do not allow channeling.

However, when ions are implanted at an ion implantation angle that does not allow channeling, the depth of ion implantation is of course shallower compared to that obtained in conditions that allow channeling, and the implanted ions do not reach a region located at a depth of 4 μm to 6 μm from the surface of the semiconductor substrate which should essentially function as the light receiving section (photoelectric conversion region), and consequently the photoelectric conversion region is not formed. In order to form the photoelectric conversion region in a region located at such a depth, it is necessary to implant ions at a high energy of not less than about 4 MeV for boron (B) as a p-type impurity, or a high energy of not less than about 2 MeV for arsenic (As) as an n-type impurity. In order to realize this ion implantation, since a large accelerator for producing the ion implantation energy is necessary, a gigantic and expensive ion implantation apparatus is required, and therefore there is a serious problem in practical applications.

As described above, in the conventional manufacturing method of a solid-state image pickup device, since the photoelectric conversion region is formed by implanting ions at an ion implantation angle θ that does not allow channeling, there is a problem that it is not easy to form the photoelectric conversion region with a necessary depth. Further, there is a problem that a large ion implantation apparatus is required to form the photoelectric conversion region with a necessary depth.

### BRIEF SUMMARY OF THE INVENTION

The present invention has been made with the aim of solving the above problems, and it is an object of the present invention to provide a manufacturing method of a solid-state image pickup device comprising a light receiving section having a photoelectric conversion region with a greater depth and less defects than a light receiving section (photoelectric conversion region) of a conventional solid-state image pickup device, the method being capable of performing stable ion implantation at low energy similar to the conventional energy and more deeply with less damage compared to the conventional example by deliberately performing ion implantation in a Si substrate with controlled crystal faces under conditions that allow channeling, and to provide a solid-state image pickup device manufactured by such a manufacturing method.

A manufacturing method of a solid-state image pickup device according to the present invention is a method of manufacturing a solid-state image pickup device comprising a charge transfer section and a light receiving section having a p-n junction in a semiconductor substrate, and characterized in that a p-type region of the p-n junction is formed by implanting ions into the semiconductor substrate under ion implantation conditions that allow channeling.

The manufacturing method of a solid-state image pickup device according to the present invention is characterized in that an n-type region of the p-n junction is formed by implanting ions into the semiconductor substrate under ion implantation conditions that allow channeling.

The manufacturing method of a solid-state image pickup device according to the present invention is characterized in that a surface of the semiconductor substrate is a (100) crystal face.

The manufacturing method of a solid-state image pickup device according to the present invention is characterized in that the ion implantation conditions include an ion implantation angle within a range of ±0.2 degrees with respect to a direction normal to the semiconductor substrate surface.

The manufacturing method of a solid-state image pickup device according to the present invention is characterized in that the ion implantation conditions include an ion implantation angle of 7 degrees with respect to a direction normal to the semiconductor substrate, and a rotation angle of 45 degrees, 135 degrees, 225 degrees, or 315 degrees with respect to a notch formed in the semiconductor substrate.

A solid-state image pickup device according to the present invention is a solid-state image pickup device comprising a charge transfer section and a light receiving section having a p-n junction in a semiconductor substrate, and characterized in that a p-type region of the p-n junction is formed by implanting ions into the semiconductor substrate under ion implantation conditions that allow channeling.

The solid-state image pickup device according to the present invention is characterized in that an n-type region of the p-n junction is formed by implanting ions into the semiconductor substrate under ion implantation conditions that allow channeling.

The solid-state image pickup device according to the present invention is characterized in that the p-type region has a depth of 4 to 6 μm from a surface of the semiconductor substrate.

According to the present invention, during the formation of the light receiving section having a p-n junction, since a p-type region is formed by implanting ions under ion implantation conditions that allow channeling, it is possible to form a deep p-type region at low ion implantation energy, thereby providing a manufacturing method of a solid-state image pickup device comprising a light receiving section with good photoelectric conversion efficiency, and such a solid-state image pickup device.

According to the present invention, during the formation of the light receiving section having a p-n junction, since an n-type region is formed by implanting ions under ion implantation conditions that allow channeling, it is possible to form a deep n-type region at low ion implantation energy, thereby providing a manufacturing method of a solid-state image pickup device comprising a light receiving section with good photoelectric conversion efficiency, and such a solid-state image pickup device.

According to the present invention, since the p and n regions of the light receiving section of the solid-state image pickup device are formed under ion implantation conditions (ion implantation angle) that allow channeling in the semiconductor substrate, it is possible to form a photodiode having a deep diffusion region (p-n junction section) by ion implantation at low energy. Moreover, since the photodiode is formed by ion implantation at low energy, it is possible to form the photodiode with less damage. Further, since a large ion implantation apparatus is not required, the light receiving section can be formed by simple ion implantation processes. Consequently, it is possible to provide a manufacturing method of a solid-state image pickup device with good photoelectric conversion efficiency and high sensitivity, and provide such a solid-state image pickup device.

The above and further objects and features of the invention will more fully be apparent from the following detailed description with accompanying drawings.

### BRIEF DESCRIPTION OF THE SEVERAL VIEWS OF THE DRAWINGS

FIG. 1 is a cross sectional view for explaining a state during a conventional manufacturing process of a solid-state image pickup device;

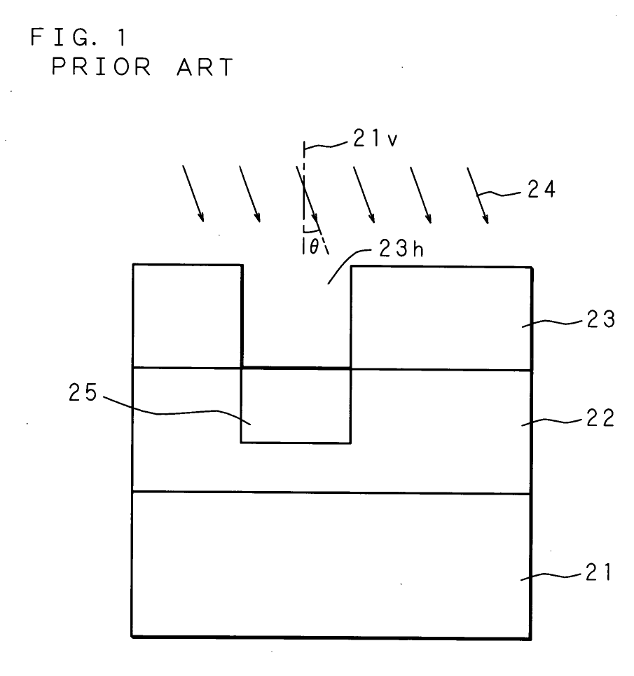

FIG. 2 is a cross sectional view for explaining the state in each manufacturing step of a solid-state image pickup device according to an embodiment of the present invention;

FIG. 3 is a cross sectional view for explaining the state in each manufacturing step of a solid-state image pickup device according to an embodiment of the present invention;

FIG. 4 is a cross sectional view for explaining the state in each manufacturing step of a solid-state image pickup device according to an embodiment of the present invention;

FIG. 5 is a cross sectional view for explaining the state in each manufacturing step of a solid-state image pickup device according to an embodiment of the present invention;

FIG. 6 is a cross sectional view for explaining the state in each manufacturing step of a solid-state image pickup device according to an embodiment of the present invention; and

FIG. 7 is a plan view for explaining a notch of a semiconductor substrate according to an embodiment of the present invention.

### DETAILED DESCRIPTION OF THE INVENTION

The following description will explain the present invention, based on the drawings illustrating an embodiment thereof.

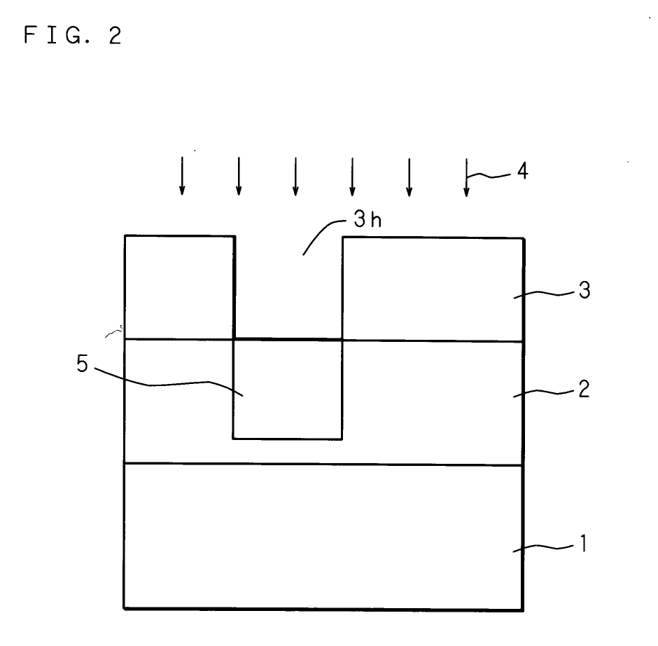

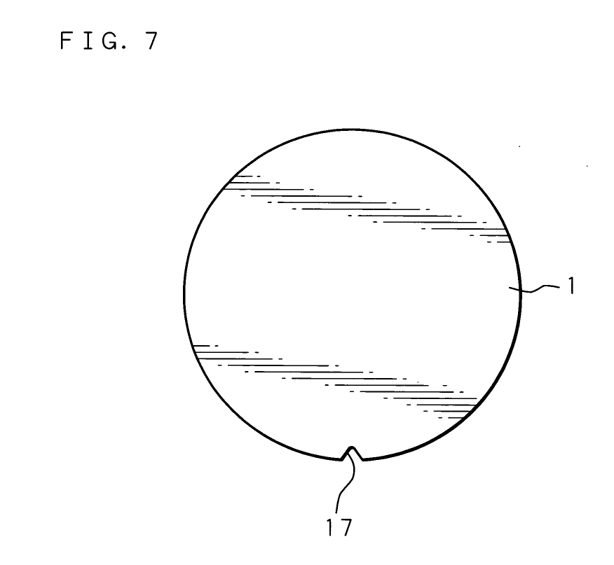

FIG. 2 through FIG. 6 are cross sectional views for explaining the state in each manufacturing step of a solid-state image pickup device according to an embodiment of the present invention. Each of the drawings shows a cross section, but oblique lines are all omitted to allow the drawings to be easily seen. FIG. 7 is a plan view for explaining a notch of a semiconductor substrate (or an orientation flat of a semiconductor substrate in a wafer state) according to an embodiment of the present invention. The notch is provided to fix a reference position of the wafer. For example, the notch has a triangular form and the top thereof is round.

FIG. 2 is a cross sectional view for explaining the state of ion implantation for forming a p-type region of a light receiving section (photoelectric conversion section). For example, a semiconductor substrate 1 composed of n-type Si single crystals is controlled so that the (100) face accuracy is within 0 to 0.5 degrees and the orientation flat or notch position accuracy is within 0 to 0.5 degrees. An n-type epitaxial layer 2 is deposited on the surface of the semiconductor substrate 1. After coating the surface of the epitaxial layer 2 with a resist film 3, an aperture section 3h corresponding to a pattern of the light receiving section is formed using a photolithography technique. Thereafter, ion implantation 4 of boron is performed to form a p-type region 5 of the light receiving section.

The ion implantation conditions of boron are a few hundred to 4 MeV for the ion implantation energy, 1×10¹⁰ to 1×10¹² ions/cm² for the implanted dose, and 0 degree±0.2 degrees for an ion implantation angle θ with respect to the direction normal to the surface of the semiconductor substrate 1. Regarding the ion implantation angle, even with an ion implantation angle (γ) of 7 degrees with respect to the normal direction and a rotation angle (Φ) of 45 degrees (135 degrees, 225 degrees, or 315 degrees) with respect to the notch 17 of the semiconductor substrate 1 (or the orientation flat of the semiconductor substrate 1 in the wafer state), the same function and effect can also be obtained. Needless to say, as technical common sense, there is some tolerance for the numerical values of the angles, 0.2 degrees, 7 degrees, 45 degrees, 135 degrees, 225 degrees, or 315 degrees. Since channeling occurs, although it may vary depending on the ion implantation conditions, it is possible to implant ions about 1.5 times deeper by implantation range Rp. It is therefore possible to easily form the p-type region 5 with a depth of around 4 to 6 μm. Further, regarding the influence on the crystal characteristics, since channeling occurs, the damage to the crystals is negligible

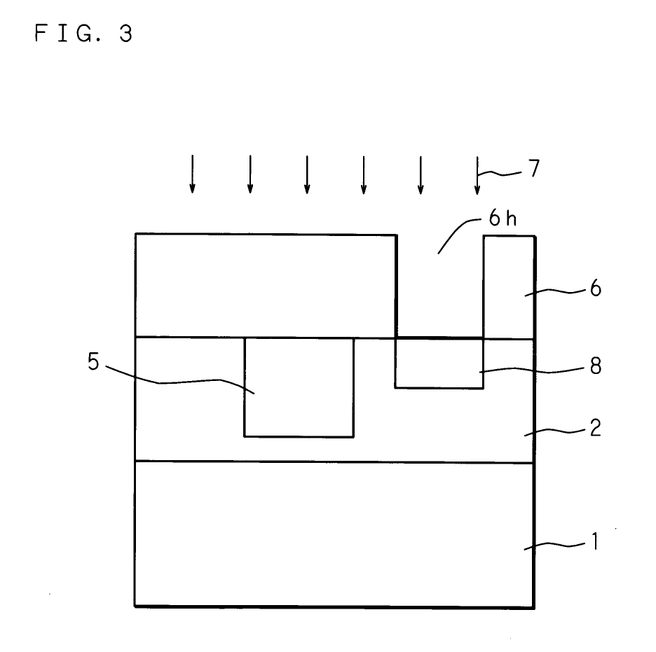

FIG. 3 is a cross sectional view for explaining the state of ion implantation for forming a p-type region of a charge transfer section. After forming the p-type region 5 of the light receiving section, the surface of the semiconductor substrate 1 is coated with a resist film 6, and an aperture section 6h corresponding to a pattern of the charge transfer section is formed using a photolithography technique. Thereafter, ion implantation 7 of boron is performed to form a charge transfer section 8 (potential well). The ion implantation conditions at this time are the same as the conventional ion implantation conditions.

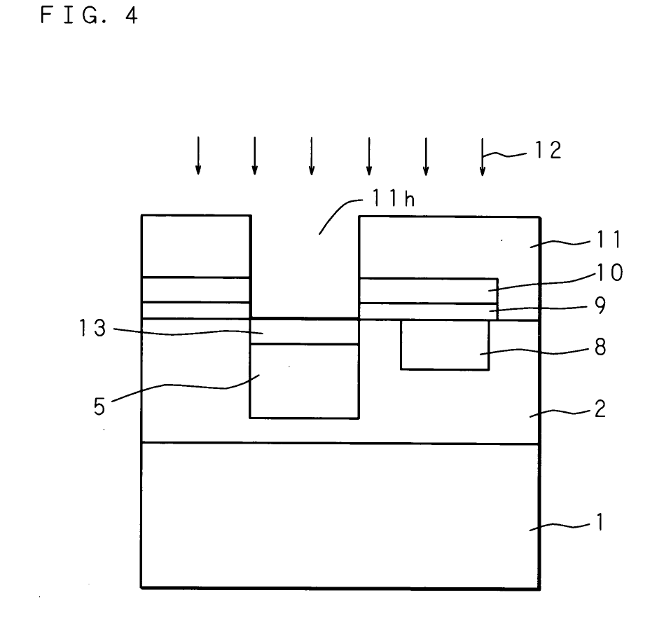

FIG. 4 is a cross sectional view for explaining the state of ion implantation for forming an n-type region of the light receiving section (photoelectric conversion section). After the step of FIG. 3, for example, a gate oxide film 9 composed of SiO₂ or SiN is formed in about 30 to 60 nm based on SiO₂. After forming a conductive Si wiring film on the gate oxide film 9, patterning is performed with a suitable pattern to form a Si wiring line 10. After coating the surface of Si wiring line 10, etc. with a resist film 11, an aperture section 11h corresponding to a light receiving pattern (p-type region 5) is formed using a photolithography technique. Then, ion implantation 12 of phosphorus is performed to form an n-type region 13 of the light receiving section in the surface of the p-type region 5. In other words, a photodiode (light receiving section) having a p-n junction is formed.

The ion implantation conditions of phosphorus are 200 to 4 MeV for the ion implantation energy, 1×10¹² to 5×10¹⁴ ions/cm² for the implanted dose, and 0 degree±0.2 degrees for an ion implantation angle (θ) with respect to the direction normal to the surface of the semiconductor substrate 1. Regarding the ion implantation angle, even with an ion implantation angle (γ) of 7 degrees with respect to the normal direction and a rotation angle (Φ) of 45 degrees (135 degrees, 225 degrees, or 315 degrees) with respect to the notch 17 of the semiconductor substrate 1 (or the orientation flat of the semiconductor substrate 1 in the wafer state), the same function and effect can also be obtained. Needless to say, as technical common sense, there is some tolerance for the numerical values of the angles, 0.2 degrees, 7 degrees, 45 degrees, 135 degrees, 225 degrees, or 315 degrees. Since channeling occurs, although it may vary depending on the ion implantation conditions, it is possible to implant ions about 1.5 times deeper by implantation range Rp. It is therefore possible to easily form the n-type region 13 with a depth of around 2 to 4 μm. Further, regarding the influence on the crystal characteristics, since channeling occurs, the damage to the crystals is negligible.

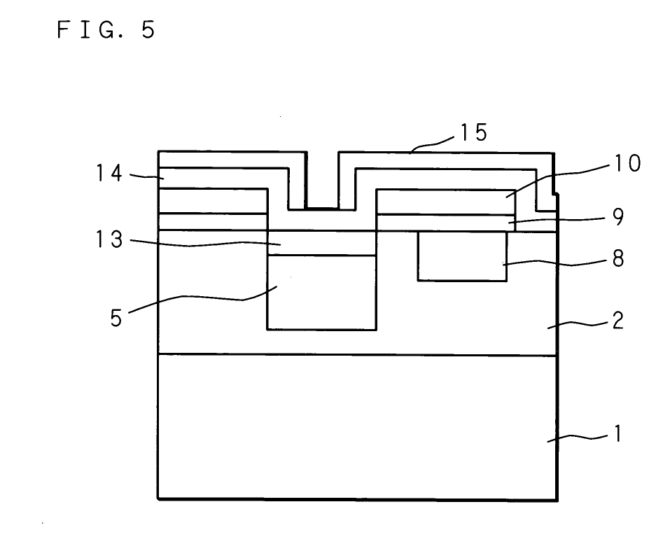

FIG. 5 is a cross sectional view for explaining the state in which a protective film and a light shielding film are formed on the surface of the semiconductor substrate. After forming the n-type region 13, boron ions are implanted (not shown) in the vicinity of the surface of the light receiving section (n-type region 13) so as to improve the efficiency of removing photoelectrically converted charge. The ion implantation conditions of boron are 20 to 100 keV for the ion implantation energy, and 1×10¹³ to 5×10¹⁵ ions/cm² for the implanted dose. Thereafter, by performing annealing, the implanted ions are activated to establish the light receiving section (p-type region 5, n-type region 13) and the transfer section 8. Next, a protective film 14 is formed on the entire surface of the semiconductor substrate 1, and then the regions other than the light receiving section is covered with a light shielding film 15.

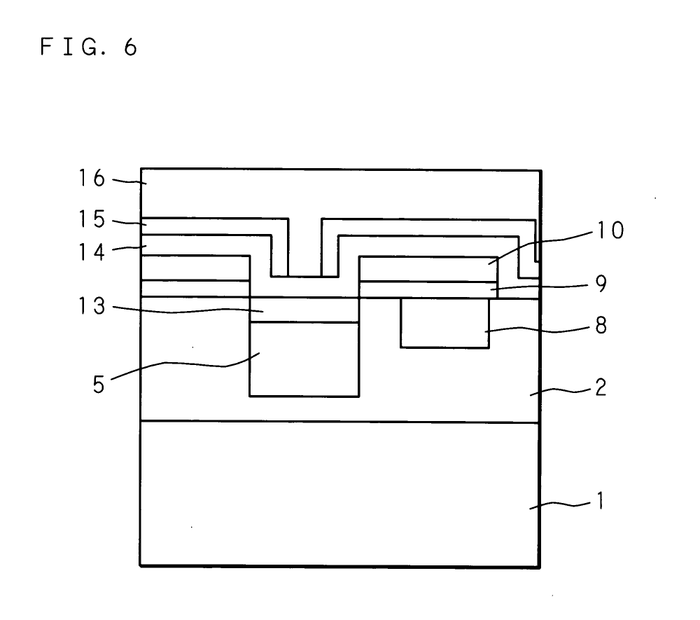

FIG. 6 is a cross sectional view for explaining the state in which an interlayer protective film is formed over the light shielding film. After forming the light shielding film 15, an interlayer protective film 16 is formed. Further, a contact hole (not shown) for making necessary contact with the respective sections formed inside the semiconductor substrate 1 is formed and wiring (not shown) composed of aluminum, etc is formed, and consequently a solid-state image pickup device is manufactured.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. A method of manufacturing a solid-state image pickup device comprising a light receiving section having a p-n junction in a semiconductor substrate, wherein
a p-type region of the p-n junction is formed by implanting ions into the semiconductor substrate under ion implantation conditions that allow channeling.

2. The method of manufacturing a solid-state image pickup device according to claim 1, wherein
an n-type region of the p-n junction is formed by implanting ions into the semiconductor substrate under ion implantation conditions that allow channeling.

3. The method of manufacturing a solid-state image pickup device according to claim 1, wherein
a surface of the semiconductor substrate is a (100) crystal face.

4. The method of manufacturing a solid-state image pickup device according to claim 1, wherein
the ion implantation conditions include an ion implantation angle within a range of ±0.2 degrees with respect to a direction normal to the semiconductor substrate surface.

5. The method of manufacturing a solid-state image pickup device according to claim 1, wherein
the ion implantation conditions include an ion implantation angle of 7 degrees with respect to a direction normal to the semiconductor substrate, and a rotation angle of 45 degrees, 135 degrees, 225 degrees, or 315 degrees with respect to a notch formed in the semiconductor substrate.

6. The method of manufacturing a solid-state image pickup device according to claim 2, wherein
a surface of the semiconductor substrate is a (100) crystal face.

7. The method of manufacturing a solid-state image pickup device according to claim 2, wherein
the ion implantation conditions include an ion implantation angle within a range of ±0.2 degrees with respect to a direction normal to the semiconductor substrate surface.

8. The method of manufacturing a solid-state image pickup device according to claim 2, wherein
the ion implantation conditions include an ion implantation angle of 7 degrees with respect to a direction normal to the semiconductor substrate, and a rotation angle of 45 degrees, 135 degrees, 225 degrees, or 315 degrees with respect to a notch formed in the semiconductor substrate.

9. The method of manufacturing a solid-state image pickup device according to claim 3, wherein
the ion implantation conditions include an ion implantation angle within a range of ±0.2 degrees with respect to a direction normal to the semiconductor substrate surface.

10. The method of manufacturing a solid-state image pickup device according to claim 3, wherein
the ion implantation conditions include an ion implantation angle of 7 degrees with respect to a direction normal to the semiconductor substrate, and a rotation angle of 45 degrees, 135 degrees, 225 degrees, or 315 degrees with respect to a notch formed in the semiconductor substrate.

11. The method of manufacturing a solid-state image pickup device according to claim 6, wherein
the ion implantation conditions include an ion implantation angle within a range of ±0.2 degrees with respect to a direction normal to the semiconductor substrate surface.

12. The method of manufacturing a solid-state image pickup device according to claim 6, wherein
the ion implantation conditions include an ion implantation angle of 7 degrees with respect to a direction normal to the semiconductor substrate, and a rotation angle of 45 degrees, 135 degrees, 225 degrees, or 315 degrees with respect to a notch formed in the semiconductor substrate.

13. A solid-state image pickup device comprising a light receiving section having a p-n junction in a semiconductor substrate, wherein
a p-type region of the p-n junction is formed by implanting ions into the semiconductor substrate under ion implantation conditions that allow channeling.

14. The solid-state image pickup device according to claim 13, wherein
an n-type region of the p-n junction is formed by implanting ions into the semiconductor substrate under ion implantation conditions that allow channeling.

15. The solid-state image pickup device according to claim 13, wherein
the p-type region has a depth of 4 to 6 μm from a surface of the semiconductor substrate.

16. The solid-state image pickup device according to claim 14, wherein
the p-type region has a depth of 4 to 6 μm from a surface of the semiconductor substrate.
